(19) United States
(12) Patent Application Publication
(10) Pub. No.: US 2021/0100099 A1
(43) Pub. Date: Apr. 1, 2021

(54) ELECTRONIC COMPONENT, ELECTRONIC APPARATUS, AND ELECTRONIC COMPONENT TEST SYSTEM

(71) Applicant: LENOVO (SINGAPORE) PTE. LTD., SINGAPORE (SG)

(72) Inventors: Hirohide Komiyama, YOKOHAMA (JP); Jun Kaminaga, TOKYO (JP); Kenji Watamura, YOKOHAMA (JP)

(73) Assignee: LENOVO (SINGAPORE) PTE. LTD., SINGAPORE (SG)

(21) Appl. No.: 16/701,905

(22) Filed: Dec. 3, 2019

(30) Foreign Application Priority Data
Oct. 1, 2019 (JP) 2019181171

(51) Int. Cl. H05K 1/11; G01R 31/319; H01R 12/70

(52) U.S. Cl. CPC H05K 1/117; H01R 12/7076; G01R 31/31905

(57) ABSTRACT

An electronic component includes: a board body including a connection pad formed in a terminal portion that is a region including at least an edge portion of a first main surface; a first cover layer covering the first main surface so that at least the terminal portion is exposed; and a second cover layer formed on the first main surface so as to surround at least part of the terminal portion. The second cover layer has a shape in a plan view that enables positioning of a fixture. The fixture includes a terminal electrically connectable to the connection pad, and is removably connectable to the board body.

### FIELD OF THE INVENTION

The present invention relates to an electronic component, an electronic apparatus, and an electronic component test system.

### BACKGROUND OF THE INVENTION

An electronic apparatus such as a laptop PC may be tested using, for example, a test apparatus corresponding to JTAG (Joint Test Action Group), for debug, EC firmware change, and the like (for example, see Japanese Patent No. 6055047).

For connection to the test apparatus, an electronic component of the electronic apparatus, such as a main board (motherboard), is provided with a dedicated connector. The main board may be provided with a resistor for a strap or for power supply to the test apparatus. In some cases, the main board needs to be modified in order to add components such as a connector and a resistor.

### SUMMARY OF THE INVENTION

The foregoing electronic apparatus cannot be tested easily, because component addition to the main board (motherboard) and the like are required.

The present invention has an object of providing an electronic component, an electronic apparatus, and an electronic component test system that ease testing.

An aspect of the present invention provides an electronic component including: a board body including a connection pad formed in a terminal portion that is a region including at least an edge portion of a first main surface; a first cover layer covering the first main surface so that at least the terminal portion is exposed; and a second cover layer formed on the first main surface so as to surround at least part of the terminal portion, wherein the second cover layer has a shape in a plan view that enables positioning of a fixture, the fixture including a terminal electrically connectable to the connection pad and being removably connectable to the board body.

The first cover layer may be a solder mask.

The second cover layer may be an ink layer.

The second cover layer is preferably formed on the first cover layer.

Another aspect of the present invention provides an electronic apparatus including the electronic component.

Yet another aspect of the present invention provides an electronic component test system including: an electronic component; and a test apparatus, wherein the electronic component includes: a board body including a connection pad formed in a terminal portion that is a region including at least an edge portion of a first main surface; a first cover layer covering the first main surface so that at least the terminal portion is exposed; and a second cover layer formed on the first main surface so as to surround at least part of the terminal portion, wherein the test apparatus includes: a fixture including a terminal electrically connectable to the connection pad, and removably connectable to the board body of the electronic component; a sub board connected to the fixture; and a test jig connected to the sub board, wherein the second cover layer has a shape in a plan view that enables positioning of the fixture, and wherein the sub board has a function of, when the fixture is connected to the terminal portion, causing the electronic component to recognize that the fixture is connected.

The fixture may include a first clamping piece and a second clamping piece for clamping the electronic component, the first clamping piece may include the terminal, and the second clamping piece may be provided with a buffer material that comes into contact with the electronic component.

The above-described aspects of the present invention provide an electronic component, an electronic apparatus, and an electronic component test system that ease testing.

### BRIEF DESCRIPTION OF THE DRAWINGS

FIG. 1 is a plan view of a main board and an electronic apparatus according to a first embodiment.

FIG. 2 is a plan view of the main board according to the first embodiment.

FIG. 3 is a sectional view of the main board according to the first embodiment.

FIG. 4 is a schematic view of a test apparatus for the main board according to the first embodiment.

FIG. 5 is a schematic view of the main board and a fixture according to the first embodiment.

FIG. 6 is a sectional view of the main board and the fixture according to the first embodiment.

FIG. 7 is an explanatory diagram of the test apparatus for the main board according to the first embodiment.

FIG. 8 is a sectional view of a fixture according to a modification.

FIG. 9 is a side view of the fixture according to the modification.

FIG. 10 is a sectional view of the fixture according to the modification.

FIG. 11 is a side view of the fixture according to the modification.

FIG. 12 is a plan view of a main board according to a second embodiment.

FIG. 13 is a sectional view of the main board according to the second embodiment.

### DETAILED DESCRIPTION OF THE INVENTION

[Electronic Component and Electronic Apparatus]

### First Embodiment

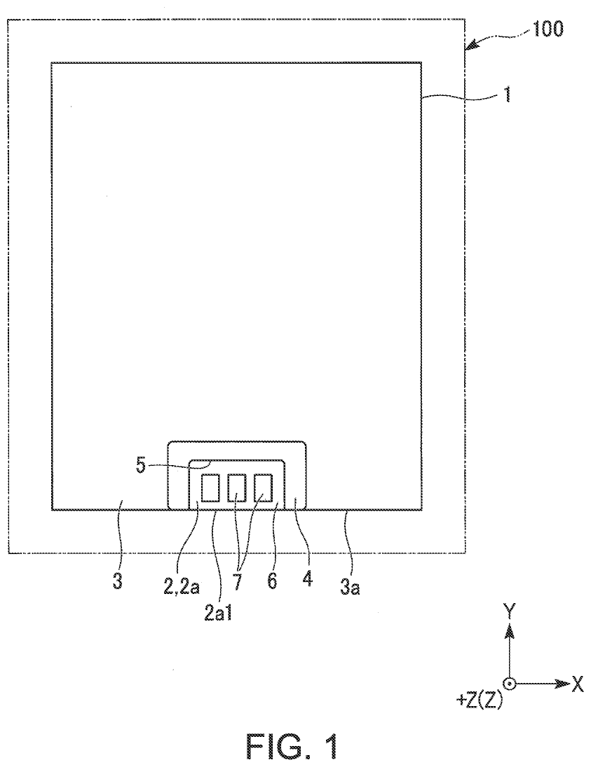

FIG. 1 is a plan view of a main board 1 (electronic component) and an electronic apparatus 100 according to a first embodiment. As illustrated in FIG. 1, the electronic apparatus 100 includes the main board 1. The main board 1 is, for example, a rigid board. The main board 1 is rectangular in a plan view. Specifically, the main board 1 is oblong in a plan view.

The electronic apparatus 100 is, for example, a laptop personal computer (laptop PC), a smartphone, a mobile phone terminal, a workstation, or a server.

An XYZ orthogonal coordinate system is hereafter used to describe the positional relationships of the structures. The X direction is the short side direction of the main board (first direction). The Y direction is the in-plane direction of the main board 1 orthogonal to the X direction (second direction). The Z direction is the thickness direction of the main board 1 orthogonal to the X direction and the Y direction (third direction). The +Z direction is an upward direction. The −Z direction is a downward direction. A view in the Z direction (up-down direction) is referred to as a plan view. The positional relationships defined herein do not limit the posture of the main board 1 during use.

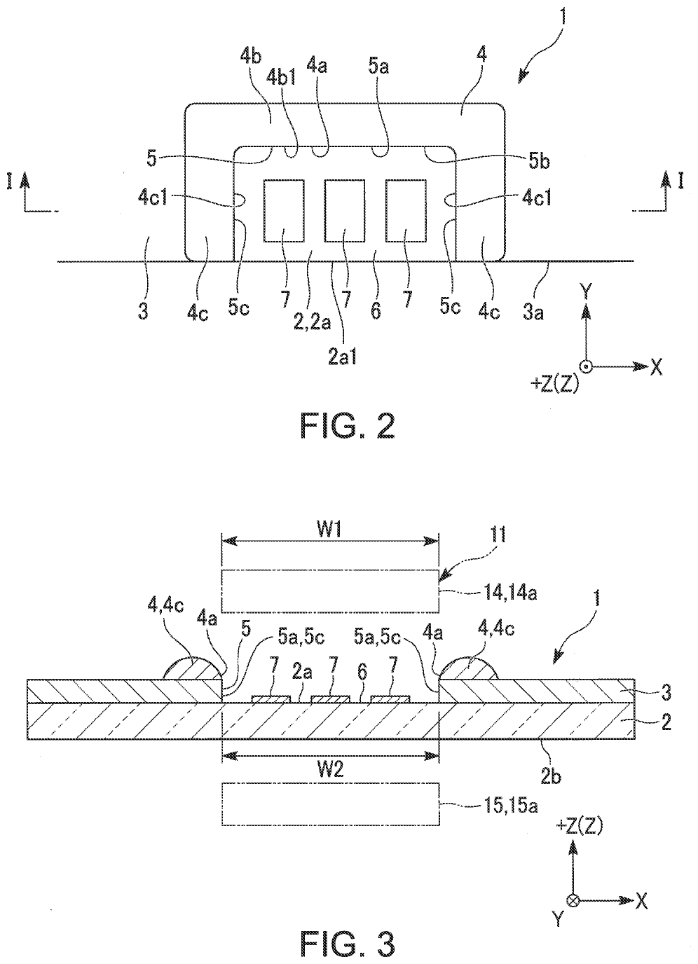

FIG. 2 is a plan view of a terminal portion 6 of the main board 1. FIG. 3 is a sectional view of the main board 1. FIG. 3 is a sectional view along I-I in FIG. 2.

As illustrated in FIG. 3, the main board 1 includes a board body 2, a first cover layer 3, and a second cover layer 4.

The board body 2 is made of a glass epoxy resin or the like. One main surface of the board body 2 is referred to as a first main surface 2a. The opposite surface of the board body 2 to the first main surface 2a is referred to as a second main surface 2b.

As illustrated in FIG. 1, an edge portion 2a1 of the first main surface 2a is an edge portion corresponding to one of the four sides of the first main surface 2a which is oblong in a plan view. One or more connection pads 7 are formed in the terminal portion 6 which is a region including part of the edge portion 2a1 of the first main surface 2a. The connection pads 7 are made of metal such as copper or a copper alloy.

The first cover layer 3 is, for example, a solder mask (solder resist). For example, the solder mask is made of solder mask ink. The first cover layer 3 can be formed using an existing solder mask production method, and therefore can be produced easily.

As illustrated in FIG. 1, an edge portion 3a is an edge portion corresponding to one of the four sides of the first cover layer 3 which is oblong in a plan view.

As illustrated in FIG. 2, a concave notch 5 is formed at the edge portion 3a of the first cover layer 3. The concave notch 5 is rectangular in a plan view. An inner peripheral edge 5a of the concave notch 5 includes a back edge 5b and a pair of side edges 5c. The back edge 5b extends in the X direction. The pair of side edges 5c extend in the Y direction from both ends of the back edge 5b toward the edge portion 2a1. The first cover layer 3 may be patterned using a photoresist technique. The first cover layer 3 may be formed by a printing method such as screen printing.

The concave notch 5 exposes the terminal portion 6 which is a partial region of the first main surface 2a. The terminal portion 6 is a rectangular region defined by the inner peripheral edge 5a. The first cover layer 3 covers the first main surface 2a so that the terminal portion 6 is exposed.

As illustrated in FIG. 3, the second cover layer 4 is formed at the surface of the first cover layer 3. That is, the second cover layer 4 is formed on the first cover layer 3. Hence, the second cover layer 4 is formed on the first main surface 2a with the first cover layer 3 being interposed therebetween.

The second cover layer 4 is, for example, an ink layer. The second cover layer 4 may be formed by a printing method such as silkscreen or inkjet. The second cover layer 4 may be formed using ink for use in printing and the like. In the case where the second cover layer 4 is an ink layer, the second cover layer 4 can be formed using an existing method, and therefore can be produced easily.

As illustrated in FIG. 2, the second cover layer 4 is preferably formed in a band shape along the inner peripheral edge 5a of the concave notch 5 of the first cover layer 3. The second cover layer 4 includes a base extension part 4b and a pair of side extension parts 4c. The base extension part 4b extends in the X direction. The pair of side extension parts 4c extend in the Y direction from both ends of the base extension part 4b toward the edge portion 3a, and reach the edge portion 3a.

An inner peripheral edge 4a of the second cover layer 4 includes an inner edge 4b1 of the base extension part 4b and inner edges 4c1 of the pair of side extension parts 4c. The inner edge 4b1 of the base extension part 4b matches the back edge 5b of the concave notch 5 in a plan view. The inner edges 4c of the pair of side extension parts 4c match the pair of side edges 5c of the concave notch 5 in a plan view. Thus, the inner peripheral edge 4a of the second cover layer 4 matches the inner peripheral edge 5a of the concave notch 5 along the entire length in a plan view.

The second cover layer 4 surrounds at least part of the terminal portion 6. In detail, the second cover layer 4 surrounds part of the terminal portion 6 along three sides of the four sides of the rectangular terminal portion 6 in a plan view.

Since the inner peripheral edge 4a of the second cover layer 4 matches the inner peripheral edge 5a of the concave notch 5 in a plan view, the second cover layer 4 has a large difference in height from the first main surface 2a of the terminal portion 6 at the inner peripheral edge 4a. Hence, the second cover layer 4 can regulate misalignment of the below-described fixture 11 (see FIG. 3) connected to the terminal portion 6 in the in-plane direction (direction along the XY plane).

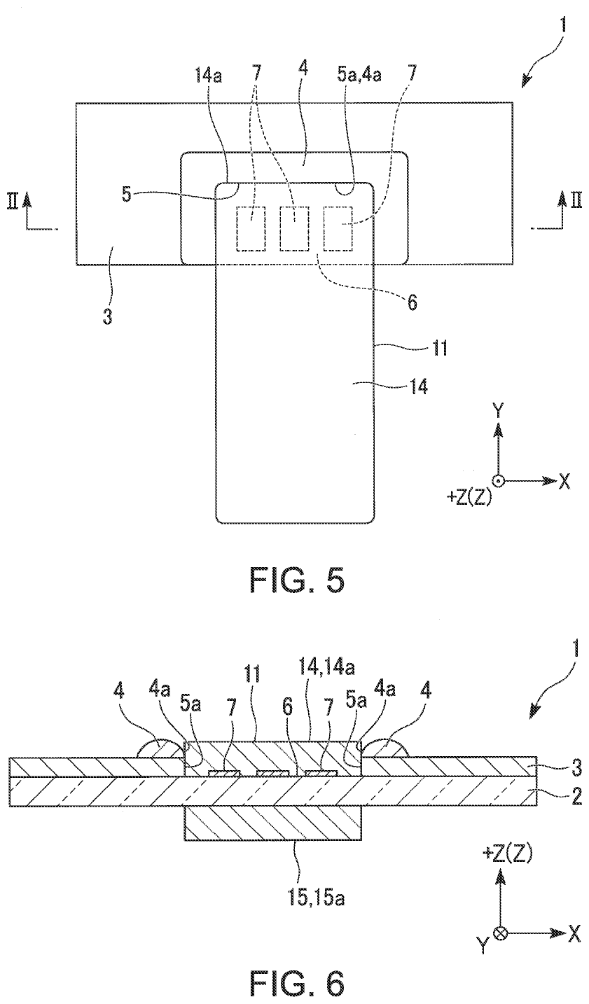

For example, the movement of the fixture 11 (see FIG. 5) in the Y direction (the upward direction in FIG. 2) is regulated by the base extension part 4b. The movement of the fixture 11 (see FIG. 5) in the X direction (the right-left direction in FIG. 2) is regulated by the pair of side extension parts 4c. The second cover layer 4 thus has such a shape that enables positioning of the fixture 11.

As illustrated in FIG. 3, the cross-sectional shape of the second cover layer 4 orthogonal to the length direction may be semicircular, semielliptic, or the like. The cross-sectional shape of the second cover layer is not limited, and may be, for example, rectangular.

[Electronic Component Test System]

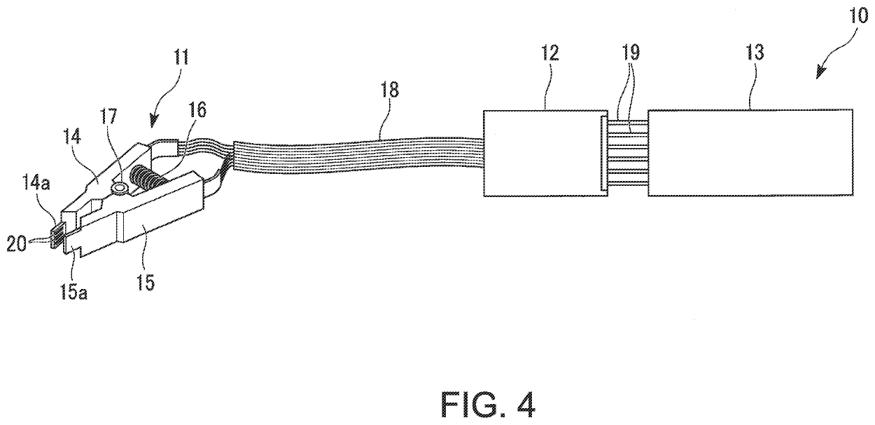

A test system according to this embodiment will be described below. The test system includes the main board 1 (see FIG. 1) and a test apparatus 10 (see FIG. 4).

FIG. 4 is a schematic view of the test apparatus 10 for the main board 1. As illustrated in FIG. 4, the test apparatus 10 includes the fixture 11, a sub board 12 (sub card), and a test jig 13.

The fixture 11 includes a first clamping piece 14, a second clamping piece 15, and a biasing member 16. The first clamping piece 14 is, for example, shaped like a long plate. Symbol 14a is a tip of the first clamping piece 14. Symbol 15a is a tip of the second clamping piece 15.

One or more pins 20 (terminals) to be connected to the connection pads 7 (see FIG. 3) are formed at the tip 14a of the first clamping piece 14. The pins 20 are formed at the inner surface of the tip 14a (i.e. the surface facing the tip 15a).

The pins 20 are made of metal such as copper or a copper alloy. The number, size, layout, etc. of the pins 20 are determined depending on the connection pads 7. The pins 20 are electrically connected to a connection line 18 via a conductor (not illustrated) provided in the first clamping piece 14.

As illustrated in FIG. 3, the width W1 of the first clamping piece 14 is less than or equal to the width W2 (dimension in the Y direction) of the terminal portion 6. The width W1 of the first clamping piece 14 is preferably 80% to 100% of the width W2 of the terminal portion 6. This eases alignment of the fixture 11 with respect to the terminal portion 6. The second clamping piece 15 is, for example, shaped like an oblong plate of the same width and the same length as the first clamping piece 14.

As illustrated in FIG. 4, the first clamping piece 14 and the second clamping piece 15 are rotatably coupled at a rotational coupling portion 17 located at an intermediate position in the length direction. The first clamping piece 14 and the second clamping piece 15 are rotatable about the rotational coupling portion 17 in a direction in which the tips 14a and 15a approach or separate from each other.

The biasing member 16 is, for example, a coil spring. The biasing member 16 biases the first clamping piece 14 and the second clamping piece 15 in a direction in which the tips 14a and 15a approach each other. Thus, the tip 14a of the first clamping piece 14 and the tip 15a of the second clamping piece 15 can clamp the board body 2 in the terminal portion 6 in the thickness direction, as illustrated in FIGS. 3 and 6.

FIG. 5 is a schematic view of the main board 1 and the fixture 11. FIG. 6 is a sectional view of the main board 1 and the fixture 11. FIG. 6 is a sectional view along II-II in FIG. 5.

As illustrated in FIGS. 5 and 6, when the tip 14a of the first clamping piece 14 and the tip 15a of the second clamping piece 15 clamp the board body 2 in the terminal portion 6 in the thickness direction, the pins 20 (see FIG. 4) of the first clamping piece 14 come into contact with the connection pads 7, and are electrically connected to the connection pads 7. The fixture 11 can thus be connected to the terminal portion 6.

The fixture 11 can be removed from the terminal portion 6, by rotating the first clamping piece 14 and the second clamping piece 15 in a direction in which the tips 14a and 15a separate from each other. The fixture 11 can thus be removably connected to the terminal portion 6.

As illustrated in FIG. 4, the sub board 12 is connected to the fixture 11 via the connection line 18.

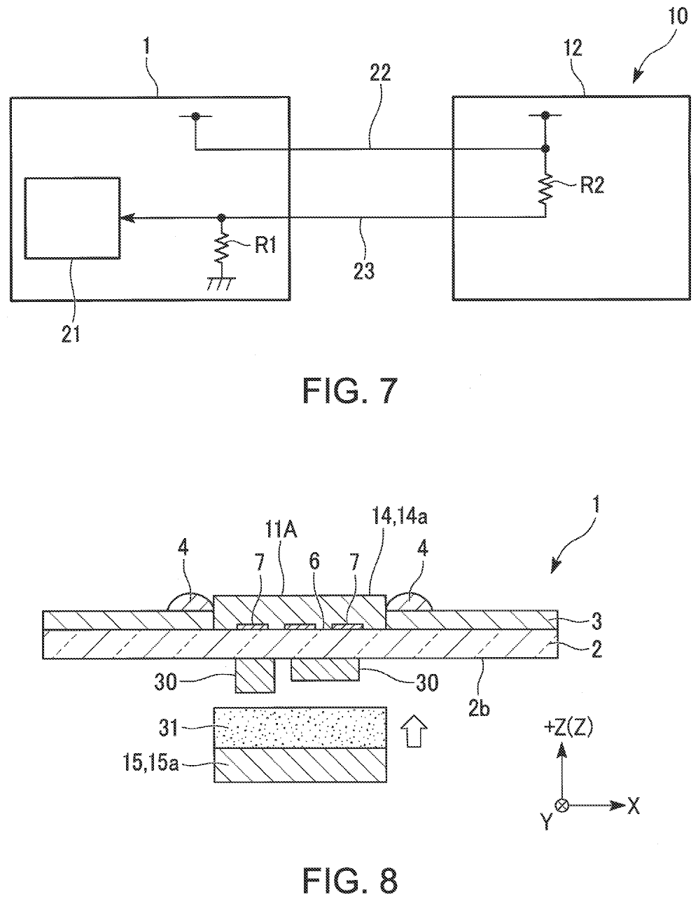

The main board 1 and the sub board 12 have a function of, when the fixture 11 is connected to the terminal portion 6 of the main board 1 (see FIGS. 5 and 6), causing the main board 1 to recognize the connection of the sub board 12 by the fixture 11. This function will be described below, with reference to FIG. 7.

FIG. 7 is a diagram of the test apparatus 10. As illustrated in FIG. 7, the main board 1 includes a microprocessor 21 and a resistor R1. The sub board 12 includes a resistor R2. The resistor R1 has a sufficiently larger resistance value than the resistor R2.

When the main board 1 and the sub board 12 are connected as a result of the fixture 11 being connected to the terminal portion 6 (see FIGS. 5 and 6), power is supplied from the main board 1 to the sub board 12 via a line 22. Based on this, a detection signal is transmitted from the sub board 12 to the microprocessor 21 in the main board 1 via a line 23.

In the case where the sub board 12 is not connected to the main board 1, the detection signal is set to “Low” by the resistor R1. When the sub board 12 is connected to the main board 1, the detection signal is set to “High” by the resistor R2. Based on the detection signal, the microprocessor 21 can recognize that the sub board 12 is connected.

The structure of the main board 1 and the sub board 12 for causing the main board 1 to recognize the connection of the sub board 12 is not limited to the example in FIG. 7. For example, a structure that enables recognition of the connection of the sub board 12 to the main board 1 by transmission/reception using a signal line for performing higher-level communication, instead of transmission/reception of the detection signal, may be used.

As illustrated in FIG. 4, the test jig 13 is connected to the sub board 12 by a connection line 19. For example, the test jig 13 corresponds to JTAG (Joint Test Action Group). JTAG is defined in IEEE 1149.1 (JTAG Boundary Scan Test Systems).

The test jig 13 can support debug, EC firmware change, etc.

In the main board 1 according to this embodiment, the second cover layer 4 is formed along the inner peripheral edge 5a of the concave notch 5, as illustrated in FIG. 3. The second cover layer 4 has a large difference in height from the first main surface 2a of the terminal portion 6 at the inner peripheral edge 4a, and accordingly can regulate misalignment of the fixture 11. The second cover layer 4 can therefore position the fixture 11 connected to the terminal portion 6. This eases testing using the test apparatus 10.

In the main board 1, the second cover layer 4 is formed on the first cover layer 3, so that the second cover layer 4 has a large difference in height from the terminal portion 6 at the inner peripheral edge 4a. This eases regulating misalignment of the fixture 11.

The test apparatus 10 illustrated in FIG. 4 has a function of causing the main board 1 to recognize the connection of the sub board 12. Accordingly, simply connecting the fixture 11 to the main board 1 enables testing. This eases testing using the test apparatus 10.

Since the test apparatus 10 is connected to the main board 1 by the fixture 11, there is no need to add, to the main board 1, a connector for connection with the test apparatus 10. Since the test apparatus 10 includes the sub board 12, component packaging for testing in the main board can be reduced. This eases testing using the test apparatus 10.

A modification of the fixture 11 (see FIGS. 5 and 6) will be described below.

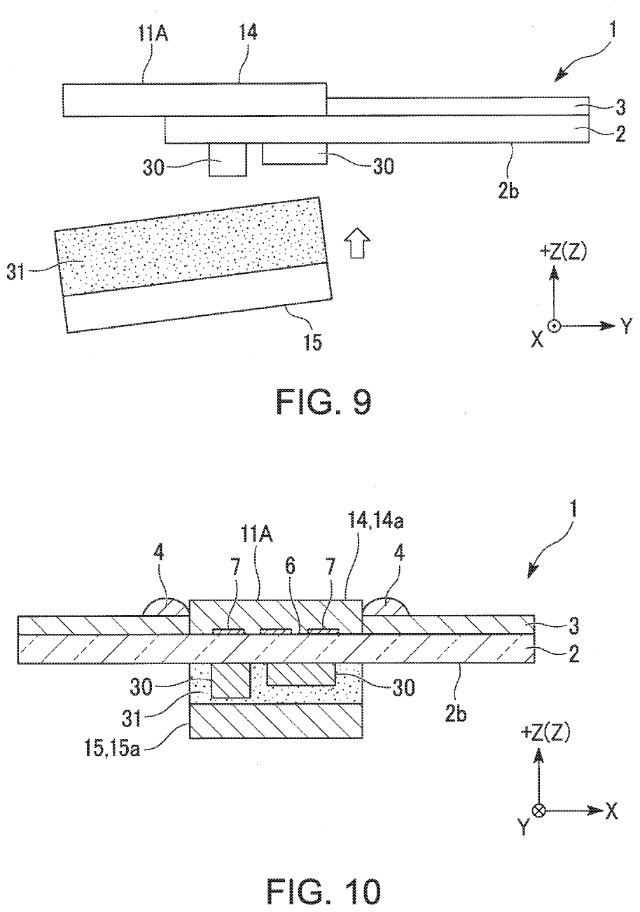

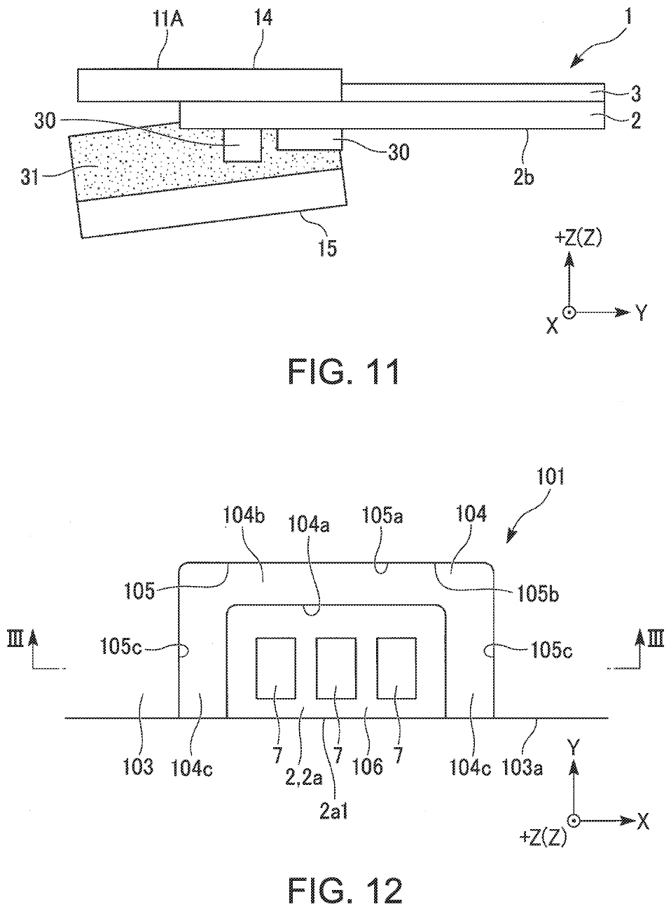

FIGS. 8 and 10 are each a sectional view of a fixture 11A according to the modification. FIGS. 9 and 11 are each a side view of the fixture 11A. FIGS. 8 and 9 illustrate the fixture 11A in a state of being not connected to the main board 1. FIGS. 10 and 11 illustrate the fixture 11A in a state of being connected to the main board 1.

As illustrated in FIGS. 8 to 11, one or more electronic components 30 (a resistor, a capacitor, etc.) may be provided on the second main surface 2b of the main board 1.

The fixture 11A differs from the fixture 11 (see FIGS. 5 and 6) in that a buffer material 31 in a layer shape (or a plate shape) is provided on the inner surface (the surface facing the first clamping piece 14) of the second clamping piece 15. The buffer material 31 is elastically compressive-deformable. The buffer material 31 is, for example, made of a foamed resin (e.g. foamed polyurethane), a fiber assembly, or a rubber (e.g. silicon rubber).

The fixture 11A includes the buffer material 31 at the second clamping piece 15, so that the load on the electronic components 30 can be reduced even in the case where the fixture 11A comes into contact with the electronic components 30. Moreover, since the buffer material 31 is compressive-deformable, the posture of the fixture 11A in a state of being connected to the main board 1 can be adjusted easily. Hence, close contact between the first clamping piece 14 and the connection pads 7 can be enhanced, and connection reliability can be improved.

The buffer material 31 may be a low-resilient buffer material. The low-resilient buffer material has impact resilience (e.g. 25° C.) (in accordance with JIS K 6400-3) of 15% or less, e.g. 1% or more and 15% or less. The low-resilient buffer material is made of a foamed resin (e.g. foamed polyurethane), a rubber (e.g. silicon rubber), or the like. The low-resilient buffer material has low resiliency, so that the load on the electronic components 30 can be reduced even in the case where the fixture 11A comes into contact with the electronic components 30.

[Electronic Component] (Second Embodiment)

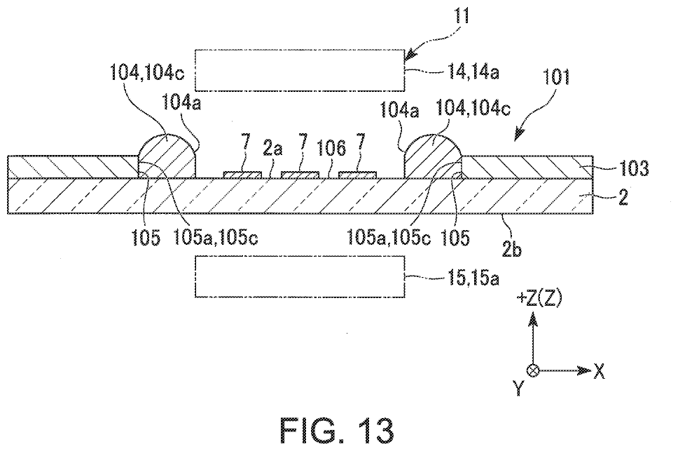

FIG. 12 is a plan view of a main board 101 (electronic component) according to a second embodiment. FIG. 13 is a sectional view of the main board 101. FIG. 13 is a sectional view along III-III in FIG. 12. The same components as those in the first embodiment are given the same symbols, and their description is omitted.

As illustrated in FIG. 13, the main board 101 includes the board body 2, a first cover layer 103, and a second cover layer 104.

The first cover layer 103 is, for example, a solder mask (solder resist).

As illustrated in FIG. 12, a concave notch 105 is formed at an edge portion 103a of the first cover layer 103. The concave notch 105 is rectangular in a plan view. An inner peripheral edge 105a of the concave notch 105 includes a back edge 105b and a pair of side edges 105c. The back edge 105b extends in the X direction. The pair of side edges 105c extend in the Y direction from both ends of the back edge 105b toward the edge portion 2a1. The first cover layer 103 covers the first main surface 2a so that a terminal portion 106 is exposed.

The second cover layer 104 is formed on the first main surface 2a, along the inner peripheral edge 105a of the concave notch 105. That is, the second cover layer 104 is formed adjacent to the first cover layer 103, along the inner peripheral edge 105a of the concave notch 105. The second cover layer 104 differs from the second cover layer 4 (see FIG. 3) in the first embodiment in that it is formed not on the first cover layer 103 but on the first main surface 2a.

The height (height from the first main surface 2a) of the second cover layer 104 is preferably greater than the height (thickness) of the first cover layer 103. As a result of the height of the second cover layer 104 being greater than the height (thickness) of the first cover layer 103, misalignment of the fixture 11 connected to the terminal portion 106 can be regulated easily.

The second cover layer 104 is, for example, an ink layer. The second cover layer 104 is preferably formed in a band shape along the inner peripheral edge 105a of the concave notch 105. The second cover layer 104 includes a base extension part 104b and a pair of side extension parts 104c. The base extension part 104b extends in the X direction. The pair of side extension parts 104c extend in the Y direction from both ends of the base extension part 104b toward the edge portion 103a, and reach the edge portion 103a.

The second cover layer 104 exposes the terminal portion 106 which is a partial region of the first main surface 2a. The terminal portion 106 is a rectangular region defined by the inner peripheral edge 104a of the second cover layer 104.

The second cover layer 104 can regulate misalignment of the fixture 11 connected to the terminal portion 106. The second cover layer 104 can therefore position the fixture 11. This eases testing using the test apparatus 10 (see FIG. 4).

Specific structures according to the present invention are not limited to the foregoing embodiments, and include design and the like within the scope of the present invention. The structures described in the foregoing embodiments may be freely combined.

For example, although the second cover layer 4 illustrated in FIG. 2 is formed along the entire length of the inner peripheral edge 5a of the concave notch 5, the second cover layer may be formed along at least part of the inner peripheral edge of the concave notch of the first cover layer. For example, the second cover layer may be L-shaped, including the base extension part 4b and one side extension part 4c illustrated in FIG. 2.

Although the main board 1 illustrated in FIG. 1 and the sub board 12 illustrated in FIG. 4 are rigid boards, the main board and the sub board may be flexible boards.

1. An electronic component comprising:
a board body including a connection pad in a terminal portion that is a region including at least an edge portion of a first main surface;
a first cover layer covering the first main surface so that at least the terminal portion is exposed; and
a second cover layer on the first main surface so as to surround at least part of the terminal portion,
wherein the second cover layer has a shape that enables positioning of a fixture, the fixture including a terminal electrically connectable to the connection pad and being removably connectable to the board body.

2. The electronic component according to claim 1, wherein the first cover layer is a solder mask.

3. The electronic component according to claim 1, wherein the second cover layer is an ink layer.

4. The electronic component according to claim 1, wherein the second cover layer is on the first cover layer.

5. An electronic apparatus comprising
an electronic component having:
a board body including a connection pad formed in a terminal portion that is a region including at least an edge portion of a first main surface;
a first cover layer covering the first main surface so that at least the terminal portion is exposed; and
a second cover layer formed on the first main surface so as to surround at least part of the terminal portion,
wherein the second cover layer has a shape in a plan view that enables positioning of a fixture, the fixture including a terminal electrically connectable to the connection pad and being removably connectable to the board body.

6. An electronic component test system comprising:
an electronic component; and
a test apparatus,
wherein the electronic component includes:
a board body including a connection pad in a terminal portion that is a region including at least an edge portion of a first main surface;
a first cover layer covering the first main surface so that at least the terminal portion is exposed; and
a second cover layer on the first main surface so as to surround at least part of the terminal portion, wherein the test apparatus includes:
a fixture including a terminal electrically connectable to the connection pad, and removably connectable to the board body of the electronic component;
a sub board connected to the fixture; and
a test jig connected to the sub board,
wherein the second cover layer has a shape that enables positioning of the fixture, and
wherein the sub board, when the fixture is connected to the terminal portion, causes the electronic component to recognize that the fixture is connected.

7. The electronic component test system according to claim 6, wherein the fixture includes a first clamping piece and a second clamping piece for clamping the electronic component,
wherein the first clamping piece includes the terminal, and
wherein the second clamping piece has a buffer material that comes into contact with the electronic component.
